(19) United States
(12) Patent Application Publication
(10) Pub. No.: US 2008/0164620 A1
(43) Pub. Date: Jul. 10, 2008

(54) MULTI-CHIP PACKAGE AND METHOD OF FABRICATING THE SAME

(75) Inventors: Yu-Yu Lin, Taipei Hsien (TW); Tsrong-Yi Wen, Taipei Hsien (TW)

Correspondence Address: J C PATENTS, INC., 4 VENTURE, SUITE 250, IRVINE, CA, 92618, US

(73) Assignee: VIA TECHNOLOGIES, INC., Taipei Hsien (TW)

(21) Appl. No.: 11/679,666

(22) Filed: Feb. 27, 2007

(30) Foreign Application Priority Data
Jan. 5, 2007 (TW) 96100461

(51) Int. Cl. H01L 23/48; H01L 21/00

(52) U.S. Cl. 257/778; 438/108; 257/E23.01; 257/E21.001

(57) ABSTRACT

A multi-chip package including a carrier, at least one first chip, and a second chip is provided. The first chip is electrically connected to the carrier and disposed on the carrier. The second chip is electrically connected to the first chip and the carrier. A part of the second chip is disposed on the first chip and another part of the second chip is disposed on the carrier. A method of fabricating the multi-chip package is also provided.

### CROSS-REFERENCE TO RELATED APPLICATION

This application claims the priority benefit of Taiwan application serial no. 96100461, filed on Jan. 5, 2007. All disclosure of the Taiwan application is incorporated herein by reference.

### BACKGROUND OF THE INVENTION

1. Field of the Invention

The present invention relates to a semiconductor element and a method of fabricating the same. More particularly, the present invention relates to a multi-chip package and a method of fabricating the same.

2. Description of Related Art

In the semiconductor industry, the production of integrated circuits (ICs) can be mainly divided into three stages: IC design, IC fabrication, and IC package.

In the IC fabrication, a chip is fabricated through the steps of wafer fabrication, IC formation, and wafer sawing. A wafer has an active surface, which generally refers to a surface having active elements of the wafer. After the ICs inside the wafer are made, a plurality of bonding pads is further disposed on the active surface of the wafer, such that the chip finally formed through the step of wafer sawing can be electrically connected outwards to a carrier via the bonding pads. The carrier is a leadframe or a package substrate, for example. The chip can be connected to the carrier by means of wire-bonding technology or flip-chip bonding technology, such that the bonding pads of the chip can be electrically connected to a plurality of bonding pads of the carrier, so as to form a chip package.

However, under the requirements of the electronic industry for maximizing the electrical performance, reducing the manufacturing cost, and enhancing the integration of the ICs and so on, the above conventional chip package with a single chip cannot meet the requirements of the current electronic industry. Therefore, the current electronic industry attempts to meet the above requirements by developing two different solutions. One is that, all the core functions are integrated in a single chip. In other words, the functions of digital logic, memory and analog, etc., are all integrated in a single chip, that is, the concept of a system on chip. Thus, this system on chip has more complicated functions than the conventional single chip. However, it still hard to develop a system on chip in practice due to the disadvantages of excessive mask processes, high cost and low yield of the system on chip. The other is that, a plurality of chips is stacked with wire-bonding technology or flip-chip bonding technology to form a multi-chip package, which is another researching trend that deserves the efforts.

### SUMMARY OF THE INVENTION

The present invention is directed to provide a multi-chip package including a carrier, at least one first chip, and a second chip. The first chip is electrically connected to the carrier, and is disposed on the carrier. The second chip is electrically connected to the first chip and the carrier. A part of the second chip is disposed on the first chip and another part of the second chip is disposed on the carrier.

The present invention is also directed to providing a method of fabricating a multi-chip package, including the following steps. First, a carrier is provided. At least one first chip is then disposed on the carrier. Then, the first chip and the carrier are electrically connected. Next, a part of a second chip is disposed on the first chip, and another part of the second chip is disposed on the carrier. Next, the second chip and the first chip are electrically connected. Finally, the second chip and the carrier are electrically connected.

In order to make the aforementioned objectives, features and advantages of the present invention comprehensible, preferred embodiments accompanied with figures are described in detail below.

### BRIEF DESCRIPTION OF THE DRAWINGS

FIG. 1A is a schematic top view of a multi-chip package of a first embodiment of the present invention.

FIG. 1B is a schematic sectional view of a multi-chip package taken along the line I-I′ of the FIG. 1A.

FIGS. 2A-2D are schematic views of the process of a method of fabricating the multi-chip package of the FIG. 1B.

FIG. 3 is a schematic top view of a multi-chip package of a second embodiment of the present invention.

FIG. 4 is a schematic top view of a multi-chip package of a third embodiment of the present invention.

FIG. 5 is a schematic sectional view of a multi-chip package of a fourth embodiment of the present invention.

FIG. 6 is a schematic sectional view of a multi-chip package of a fifth embodiment of the present invention.

### DESCRIPTION OF EMBODIMENTS

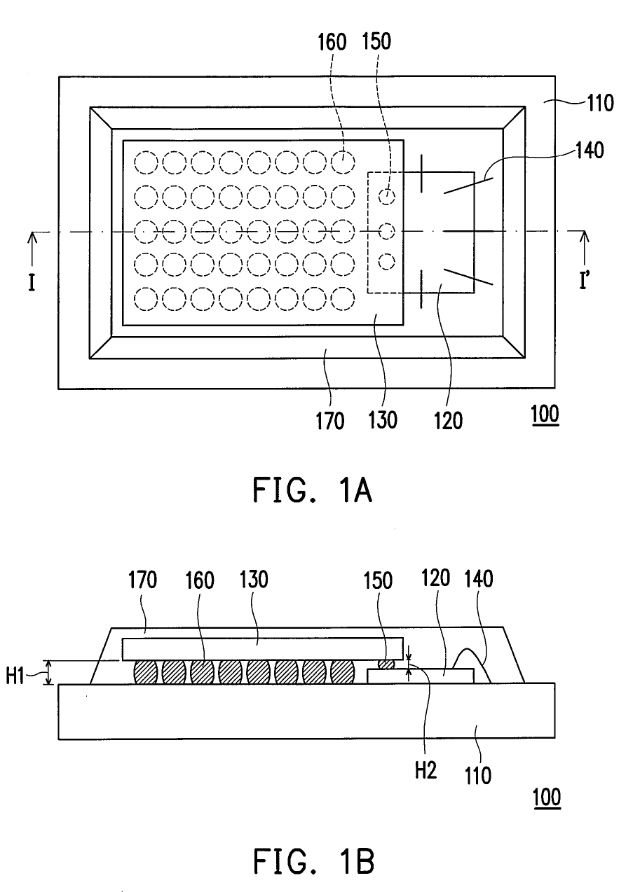

FIG. 1A is a schematic top view of a multi-chip package of a first embodiment of the present invention, and FIG. 1B is a schematic sectional view of the multi-chip package taken along the line I-I′ of the FIG. 1A. Referring to FIGS. 1A and 1B, the multi-chip package 100 of the first embodiment includes a carrier 110, at least a chip 120, and a chip 130. The carrier 110 is, for example, a substrate, and the combination of the chip 120 and the chip 130 may be a combination of a memory chip, a north bridge chip, a graphic chip, and a central processing unit chip and the like. For example, the chip 120 may be a memory chip, and the chip 130 may be a graphic chip. The chip 120 is electrically connected to the carrier 110, and is disposed on the carrier 110. The chip 130 is electrically connected to the chip 120 and the carrier 110. A part of the chip 130 is disposed on the chip 120, and another part of the chip 130 is disposed on the carrier 110.

The transmission path of an electrical signal between the elements of the multi-chip package 100 is short, as the chip 130 and the carrier 110 may transmit the electrical signal to each other directly, the chip 120 and the carrier 110 may also transmit the electrical signal to each other directly, and the chip 130 and the chip 120 may also transmit the electrical signal to each other directly. Therefore, the electrical efficiency of the multi-chip package 100 is better. Further, when the multi-chip package 100 operates, the chip 120 and the chip 130 may both transmit the generated heat through the backs thereof or the carrier 110 to the external environment, and thus, the multi-chip package 100 will have a better heat-dissipating capacity.

The multi-chip package 100 of the first embodiment further includes at least one electrical connection element 140 (a plurality of electrical connection elements 140 is schematically shown in FIG. 1A), at least one electrical connection element 150 (a plurality of electrical connection elements 150 is schematically shown in FIG. 1A), and at least one electrical connection element 160 (a plurality of electrical connection elements 160 is schematically shown in FIGS. 1A and 1B). For example, each of the electrical connection elements 140 may be a bonding wire (as shown in FIGS. 1A and 1B), a flexible circuit board, or other suitable electrical connection elements, for electrically connecting the chip 120 and the carrier 110. Each of the electrical connection elements 150 may be a bump (as shown in FIGS. 1A and 1B), a conductive paste or other suitable electrical connection elements, and is disposed between the chip 130 and the chip 120 for electrically connecting the chip 130 and the carrier 120. Further, the electrical connection elements 150 are arranged in a line in FIG. 1A, and may also be arranged in a plurality of lines. Each of the electrical connection elements 160 may be a bump, and is disposed between the chip 130 and the carrier 110 for electrically connecting the chip 130 and the carrier 110. It should be noted that, the height H1 of each of the electrical connection elements 160, such as bumps, is greater than the height H2 of each of the electrical connection elements 150, such as bumps.

In the first embodiment, the multi-chip package 100 further includes an encapsulant 170 encapsulating the chips 120, 130, the electrical connection elements 140, 150, 160, and a part of the carrier 110. In another embodiment (not shown), the chip 120, the side of the chip 130, the electrical connection elements 140, 150, 160, and a part of the carriers 110 are encapsulated by the encapsulant 170, such that the back of the chip 130 is exposed, thereby improving the heat-dissipating capacity of the chip 130. The encapsulant 170 may protect the encapsulated elements from the influence of the external temperature, moisture, and noise, and provide a hand held configuration.

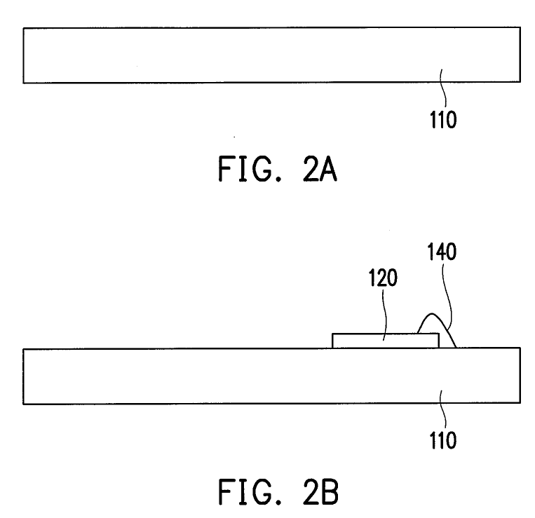

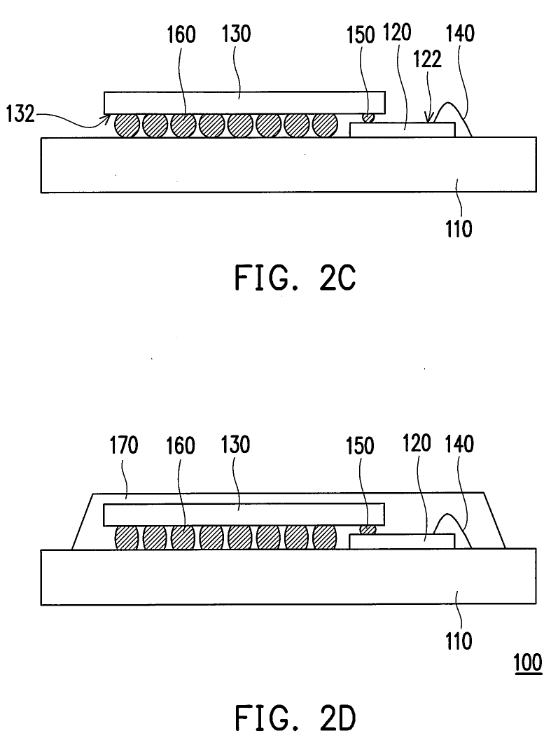

FIGS. 2A-2D are schematic views of the process of a method of fabricating the multi-chip package of the FIG. 1B. First, referring to FIG. 2A, a carrier 110 is provided, and the carrier 110 may be a substrate. Then, referring to FIG. 2B, the chip 120 is disposed on the carrier 110. In the first embodiment, the chip 120 may be disposed on the carrier 110 by an adhesive layer (not shown).

Then, referring to FIG. 2B, the chip 120 and the carrier 110 are electrically connected. In the first embodiment, the chip 120 may be electrically connected to the carrier 110 through a plurality of electrical connection elements 140, and the electrical connection elements 140 may be bonding wires. In other words, the chip 120 may be connected to the carrier 110 by means of the wire-bonding technology.

Next, referring to FIG. 2C, a part of the chip 130 is disposed on the chip 120, and another part of the chip 130 is disposed on the carrier 110. It should be noted that, the electrical connection elements 150 and 160, such as bumps, may be preformed on a surface 132 of the chip 130 (for example, an active surface of the chip 130) by way of electroplating or stencil printing. However, the electrical connection elements 150, such as bumps, may also be selectively preformed on a surface 122 of chip 120 away from the carrier 110 (for example, an active surface of the chip 120) depending on the demands of the designer.

Next, referring to FIG. 2D, the electrical connection elements 150, such as bumps, may be reflowed, so as to electrically connect the chip 130 and the chip 120. Then, the electrical connection elements 160, such as bumps, may be reflowed, so as to electrically connect the chip 130 and the carrier 110. Then, the encapsulant 170 may be formed to encapsulate the chips 120, 130, the electrical connection elements 140, 150, 160, and a part of the carrier 110. In the first embodiment, the reflow of the electrical connection elements 150 and 160 may be completed in the same step. In addition, as known from the steps shown in FIGS. 2C and 2D, the chip 130 may be bonded to the chip 120 and the carrier 110 by means of the flip-chip bonding technology. Further, as known from the above, the method of fabricating the multi-chip package 100 of the first embodiment is compatible with the existing process.

It must be illustrated that, in another embodiment (not shown), the abovementioned step shown in FIG. 2B may be performed after the reflowing step described above is completed. In other words, after the chip 130 is bonded to the chip 120 and the carrier 110 by means of the flip-chip bonding technology, the electrical connection elements 140, such as the bonding wires, are formed to electrically connect the chip 120 and the carrier 110.

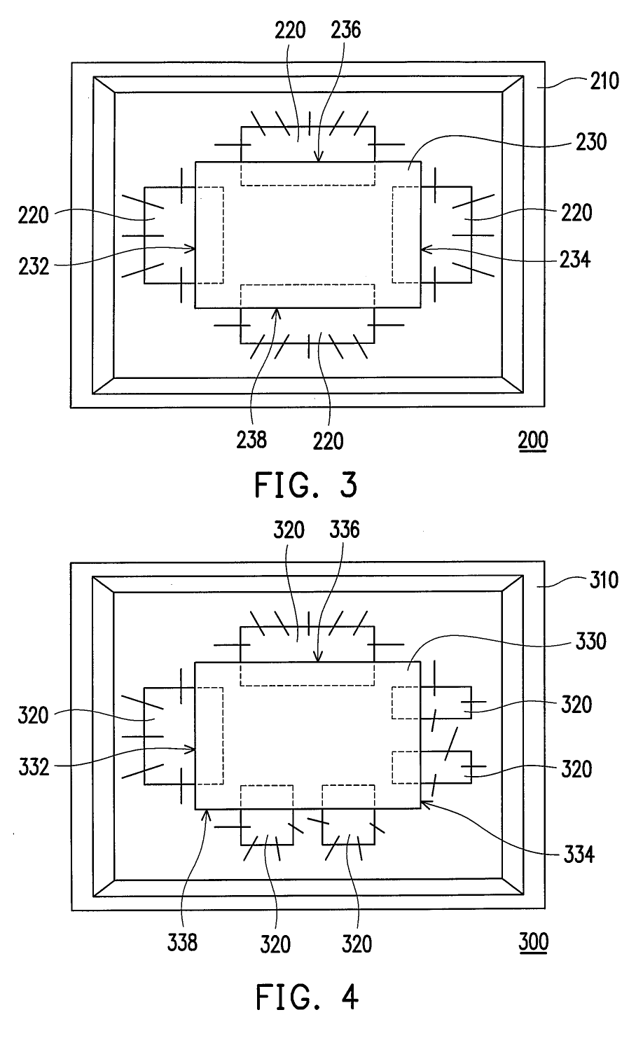

FIG. 3 is a schematic top view of a multi-chip package of a second embodiment of the present invention. Referring to FIG. 3, the main difference between the multi-chip package 200 of the second embodiment and the multi-chip package 100 of the first embodiment is that the multi-chip package 200 of the second embodiment includes a plurality of chips 220 respectively disposed below a plurality of sides of the chip 230, and the number of the chips 220 disposed below each side of the chip 230 is the same. As shown in the FIG. 3, the chip 230 has four sides 232, 234, 236, and 238, wherein the side 232 is opposite to the side 234, the side 232 is adjacent to the sides 236 and 238, and one chip 220 is disposed below each of sides 232, 234, 236, and 238. Certainly, in other embodiments (not shown), the chips 220 may be disposed below two or three sides of the chip 230, depending on the demands of the designer.

FIG. 4 is a schematic top view of a multi-chip package of a third embodiment of the present invention. Referring to FIG. 4, the main difference between the multi-chip package 300 of the third embodiment and the multi-chip packages 100 and 200 of the abovementioned embodiments is that the multi-chip package 300 of the third embodiment includes a plurality of chips 320 disposed below a plurality of sides of the chip 330, and the number of the chips 320 disposed below each side of the chip 330 may be the same or different. As shown in the FIG. 4, the chip 330 has four sides 332, 334, 336, and 338, wherein the side 332 is opposite to the side 334, the side 332 is adjacent to the sides 336 and 338, two chips 320 are disposed below each of the two sides 334 and 338, and one chip 320 is disposed below each of the other two sides 332 and 336. Certainly, in other embodiments (not shown), the chips 320 may be disposed below one, two or three sides of the chip 330, depending on the demands of the designer.

The method of fabricating a multi-chip package of the second embodiment and the third embodiment of the present application is similar to the above-mentioned method of fabricating multi-chip package 100 of the FIG. 1B. The main difference is that, an area (not shown) that is prepared for disposing the chip 230 or 330 will be preserved on the carrier 210 or 310 in advance when a plurality of chips 220 or 320 is disposed on the carrier 210 or 310. The size of the area is approximately consistent with the chip 230 or the chip 330. Then, the chips 220 or 320 are disposed above a plurality of borders of this area, depending on different demands. Thus, the orthogonal projection of the chip 230 or 330 on the carrier 210 or 310 almost concides the preserved area after the chip 230 or 330 has been disposed. In other words, the sides 232, 234, 236, and 238 of the chip 230 may be aligned with the borders of the previously persevered area on the carrier 210. The sides 332, 334, 336, and 338 of the chip 330 may be aligned with the borders of the previously persevered area on the carrier 310. Further, for the chip 320 on the left of the FIG. 4, the chip 320 is located between the side 332 of the upper chip 330 and the border of the preserved area of the lower carrier 310, wherein the border of the lower preserved area is aligned with the side 332.

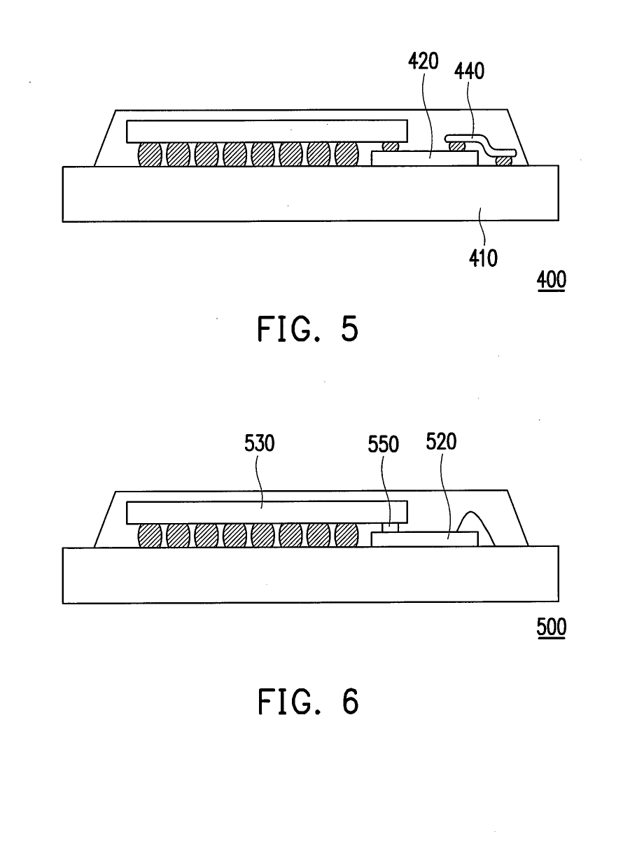

FIG. 5 is a schematic sectional view of a multi-chip package of a fourth embodiment of the present invention. Referring to FIG. 5, the main difference between the multi-chip package 400 of the fourth embodiment and the multi-chip package 100 of the first embodiment is that electrical connection elements 440 electrically connecting a chip 420 and a carrier 410 may be flexible circuits, such as flexible circuit boards or the like. In other words, the chip 420 may be connected to the carrier 410 by means of the tap automated bonding technology. Certainly, for different demands, bonding wires or other suitable electrical connection elements may be used as the electrical connection elements 440.

FIG. 6 is a schematic sectional view of a multi-chip package of a fifth embodiment of the present invention. Referring to FIG. 6, the main difference between the multi-chip package 500 of the fifth embodiment and the multi-chip package 100 of the first embodiment is that electrical connection elements 550 electrically connecting a chip 530 and a chip 520 may be conductive pastes, such as anisotropic conductive pastes. Certainly, for different demands, bumps or other suitable electrical connection elements may be used as the electrical connection elements 550.

To sum up, the chip package and the method of fabricating the same of the present invention have the following advantages.

1. The transmission path of an electrical signal between the elements of the multi-chip package is short, as each of the chips and the carrier may transmit the electrical signal to one another directly, and the chips may also transmit the electrical signal to one another directly. Therefore, the electrical efficiency of the multi-chip package of the present invention is better.

2. When the multi-chip package of the present invention operates, the chips may both transmit the generated heat through the backs thereof or the carrier to the external environment, and thus, the multi-chip package of the present invention will have a better heat-dissipating capacity.

3. The method of fabricating the multi-chip package of the present invention will not increase the cost for manufacturing equipment, as it is compatible with the existing process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-chip package, comprising:
a carrier;
at least one first chip, electrically connected to the carrier, wherein the first chip is disposed on the carrier; and
a second chip, electrically connected to the first chip and the carrier, wherein a part of the second chip is disposed on the first chip and another part of the second chip is disposed on the carrier.

2. The multi-chip package as claimed in claim 1, further comprising at least one first electrical connection element electrically connecting the first chip and the carrier.

3. The multi-chip package as claimed in claim 2, wherein the first electrical connection element is a bonding wire or a flexible circuit board.

4. The multi-chip package as claimed in claim 1, further comprising at least one second electrical connection element electrically connecting the second chip and the first chip.

5. The multi-chip package as claimed in claim 4, wherein the second electrical connection element is a bump or a conductive paste.

6. The multi-chip package as claimed in claim 1, further comprising at least one third electrical connection element electrically connecting the second chip and the carrier.

7. The multi-chip package as claimed in claim 6, wherein the third electrical connection element is a bump.

8. The multi-chip package as claimed in claim 1, wherein the second chip has a first side and a second side opposite to the first side, and the multi-chip package further comprises at least one third chip electrically connected to the carrier and disposed on the carrier is partially covered by the second chip, and the first chip and the third chip are respectively disposed below the first side and the second side of the second chip.

9. The multi-chip package as claimed in claim 8, wherein the second chip has a first side and at least one third side adjacent to the first side, and the first chip and the third chip are respectively disposed below the first side and the third side of the second chip.

10. The multi-chip package as claimed in claim 1, wherein the second chip has a first side and at least one second side adjacent to the first side, and the multi-chip package further comprises at least one third chip electrically connected to the carrier and disposed on the carrier is partially covered by the second chip, and the first chip and the third chip are respectively disposed below the first side and the second side of the second chip.

11. A method of fabricating a multi-chip package, comprising:
providing a carrier;
disposing at least one first chip on the carrier;
electrically connecting the first chip and the carrier;
disposing a part of a second chip on the first chip, and disposing another part of the second chip on the carrier;
electrically connecting the second chip and the first chip; and
electrically connecting the second chip and the carrier.

12. The method of fabricating a multi-chip package as claimed in claim 11, wherein the step of electrically connecting the first chip and the carrier comprises electrically connecting the first chip and the carrier through at least one first electrical connection element.

13. The method of fabricating a multi-chip package as claimed in claim 12, wherein the first chip and the carrier are electrically connected through at least one bonding wire, or the first chip and the carrier are electrically connected through at least one flexible circuit board.

14. The method of fabricating a multi-chip package as claimed in claim 11, wherein the step of electrically connecting the second chip and the first chip comprises electrically connecting the second chip and the first chip through at least one second electrical connection element.

15. The method of fabricating a multi-chip package as claimed in claim 14, wherein the second chip and the first chip are electrically connected through at least one bump, or the second chip and the first chip are electrically connected through at least one conductive paste.

16. The method of fabricating a multi-chip package as claimed in claim 11, wherein the step of electrically connecting the second chip and the carrier comprises electrically connecting the second chip and the carrier through at least one third electrical connection element.

17. The method of fabricating a multi-chip package as claimed in claim 16, wherein the second chip and the carrier are electrically connected through at least one bump.

18. The method of fabricating a multi-chip package as claimed in claim 11, wherein the step of disposing the first chips on the carrier comprises:
preserving an area on the carrier for disposing the second chip, wherein the area has a first border and a second border opposite to the first border; and
disposing a part of the first chips above the first border of the area; and
disposing the other part of the first chips above the second border of the area.

19. The method of fabricating a multi-chip package as claimed in claim 11, wherein the step of disposing the first chips on the carrier comprises:
preserving an area on the carrier for disposing the second chip, wherein the area has a first border and at least one second border adjacent to the first border;
disposing a part of the first chips above the first border of the area; and
disposing the other part of the first chips above the second border of the area.

20. The method of fabricating a multi-chip package as claimed in claim 11, wherein the step of disposing the first chips on the carrier comprises:
preserving an area on the carrier for disposing the second chip, wherein the area has a first border, a second border, and at least one third border, the second border is opposite to the first border, and the third border is adjacent to the first border;
disposing a part of the first chips above the first border of the area;
disposing another part of the first chips above the second border of the area; and
disposing the other part of the first chips above the third border of the area.
